(19) United States
(12) Patent Application Publication
(10) Pub. No.: US 2015/0114691 A1
(43) Pub. Date: Apr. 30, 2015

(54) CORE SUBSTRATE AND METHOD FOR MANUFACTURING THE SAME

(71) Applicant: SAMSUNG ELECTRO-MECHANICS CO., LTD., Suwon-Si (KR)

(72) Inventors: Jin Ho HONG, Suwon-Si (KR); Sang Hyun Shin, Suwon-Si (KR); Sa Yong Lee, Suwon-si (KR); Sung Han Kim, Suwon-Si (KR); Keun Yong Lee, Suwon-Si (KR)

(73) Assignee: SAMSUNG ELECTRO-MECHANICS CO., LTD., Suwon-Si (KR)

(21) Appl. No.: 14/525,037

(22) Filed: Oct. 27, 2014

(30) Foreign Application Priority Data
Oct. 28, 2013 (KR) 10-2013-0128590

(51) Int. Cl. H05K 1/03; H05K 1/18; H05K 1/11

(52) U.S. Cl. CPC H05K 1/0306; H05K 1/115; H05K 1/188; H05K 2201/0116; H05K 2201/0175; H05K 2201/0158; H05K 2201/10015
USPC 174/251; 29/832

(57) ABSTRACT

Disclosed herein are a core substrate and a method for manufacturing the same. According to a preferred embodiment of the present invention, a core substrate includes: a porous scaffold formed with a void; an insulating material formed to fill a void of the porous scaffold; and an electronic device embedded into the porous scaffold and the insulating material and having internal electrodes exposed on both surfaces thereof.

### CROSS REFERENCE TO RELATED APPLICATION

This application claims the benefit of Korean Patent Application No. 10-2013-0128590, filed on Oct. 28, 2013, entitled “Core Substrate And Method For Manufacturing The Same”, which is hereby incorporated by reference in its entirety into this application.

### BACKGROUND OF THE INVENTION

1. Technical Field

The present invention relates to a core substrate and a method for manufacturing the same.

2. Description of the Related Art

With the increased demand for multi-functional, small and thin cellular phones and electronic devices of information technology (IT), a technology of embedding electronic components, such as ICs, semiconductor chips, active devices and passive devices, into a substrate so as to cope with the technological demands has been required. Recently, technologies of embedding components into the substrate by various methods have been developed.

According to the general component embedded substrate, a cavity is formed into an insulating layer of the substrate and electronic components, such as various devices, ICs, and semiconductor chips, are embedded into the cavity. Next, an adhesive resin, such as prepreg, is applied into the cavity and on an insulating layer into which the electronic components are embedded. As described above, the electronic components are fixed and the insulating layer is formed, by applying the adhesive resin (U.S. Pat. No. 7,886,433).

### SUMMARY OF THE INVENTION

The present invention has been made in an effort to provide a core substrate embedded with electronic devices and a method for manufacturing the same.

Further, the present invention has been made in an effort to provide a core substrate and a method for manufacturing the same capable of improving adhesion with embedded electronic devices.

In addition, the present invention has been made in an effort to provide a core substrate and a method for manufacturing the same capable of reducing manufacturing costs and time.

According to a preferred embodiment of the present invention, there is provided a core substrate, including: a porous scaffold formed with a void; an insulating material formed to fill a void of the porous scaffold; and an electronic device embedded into the porous scaffold and the insulating material and having internal electrodes exposed on both surfaces thereof.

The porous scaffold may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of urea resin, phenol resin, a polystyrene resin, and a combination thereof.

The insulating material may be a prepreg.

The internal electrodes may be exposed from both surfaces of the electronic device.

The internal electrodes may be exposed from upper and lower surfaces of the electronic device.

The core substrate may further include: a metal layer formed on a surface opposite to a surface which contacts the porous scaffold of the insulating material.

The core substrate may further include: vias formed on both sides of the electronic device to electrically connect the metal layer to the internal electrode.

The metal layer may be electrically connected to the internal electrode by contacting the internal electrode.

The electronic device may be a multi layer ceramic capacitor (MLCC).

According to another preferred embodiment of the present invention, there is provided a method for manufacturing a core substrate, including: mounting electronic devices having internal electrodes exposed on both surfaces thereof on a firing substrate; applying and sintering a polymer slurry on the firing substrate; forming a porous scaffold by firing the sintered polymer slurry; removing the firing substrate; and filling the insulating material in a void of the porous scaffold by stacking and pressing an insulating material on one surface or both surfaces of the porous scaffold.

The polymer slurry may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of urea resin, phenol resin, a polystyrene resin, and a combination thereof.

In the filling of the insulating material in the void of the porous scaffold, the insulating material may be a prepreg.

The method for manufacturing a core substrate may further include: after the filling of the insulating material in the void of the porous scaffold, forming a metal layer formed on a surface opposite to a surface which contacts the porous scaffold of the insulating material.

The method for manufacturing a core substrate may further include: after the forming of the metal layer, forming a via hole on the porous scaffold and the insulating material so that the internal electrode of the electronic device is exposed; and electrically connecting the metal layer with the internal electrode by forming a conductive material in the via hole.

In the forming of the metal layer, the metal layer may be electrically connected to the internal electrode of the electronic device by contacting the internal electrode of the electronic device.

In the filling of the insulating material in the void of the porous scaffold, the insulating material may further include a metal layer formed on a surface opposite to a surface which contacts the porous scaffold.

The method for manufacturing a core substrate may further include: after the filling of the insulating material in the void of the porous scaffold, forming a via hole on the porous scaffold and the insulating material so that the internal electrode of the electronic device is exposed; and electrically connecting the metal layer with the internal electrode by forming a conductive material in the via hole.

In the filling of the insulating material in the void of the porous scaffold, the metal layer may be electrically connected to the internal electrode of the electronic device by contacting the internal electrode of the electronic device.

The internal electrodes may be exposed from both surfaces of the electronic device.

The internal electrodes may be exposed from upper and lower surfaces of the electronic device.

The electronic device may be a multi layer ceramic capacitor (MLCC).

The electronic device may be in a non-sintered and non-firing state.

In the applying and sintering of the polymer slurry on the firing substrate, the electronic device may be sintered.

In the forming of the porous scaffold by firing the sintered polymer slurry, the electronic device may be fired.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a core substrate according to a preferred embodiment of the present invention;

FIGS. 2 to 8 are exemplified diagrams illustrating a method for manufacturing a core substrate according to a preferred embodiment of the present invention;

FIG. 9 is an exemplified diagram illustrating a core substrate according to another preferred embodiment of the present invention; and

FIGS. 10 to 14 are exemplified diagrams illustrating a method for manufacturing a core substrate according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

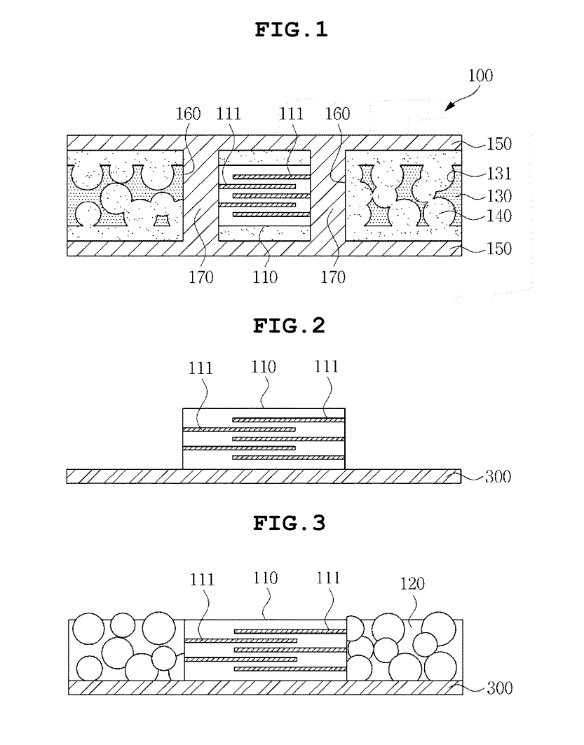

FIG. 1 is an exemplified diagram illustrating a core substrate according to a preferred embodiment of the present invention.

Referring to FIG. 1, a core substrate 100 according to a preferred embodiment of the present invention may be embedded with an electronic device 110.

The electronic device 110 may be embedded into the core substrate 100. The electronic device 110 according to the preferred embodiment of the present invention may be a multi layer ceramic capacitor (MLCC) in which an external electrode is not formed.

Internal electrodes 111 may be formed on both surfaces of the electronic device 110. The internal electrode 111 according to the preferred embodiment of the present invention has stability at a firing temperature, and any material which may be used for the internal electrode of the MLCC may be applied. Further, according to the preferred embodiment of the present invention, the internal electrodes 111 may be exposed from both sides of the electronic device 110. Here, exposing the internal electrodes 111 from both sides of the electronic device 110 is to describe the fact that the internal electrodes 111 are exposed on a vertical line of a metal layer 150. As illustrated in FIG. 1, the electronic device 110 having the internal electrodes 111 exposed on both sides thereof may be a device which is horizontally embedded into the core substrate 100.

The core substrate 100 may include a porous scaffold 130, an insulating material 140, a metal layer 150, and a via 170.

The porous scaffold 130 may have a porous structure including a plurality of voids. The porous scaffold 130 according to the preferred embodiment of the present invention may be made of a material having excellent thermal stability. For example, the porous scaffold 130 may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of porous inorganic material and urea resin, phenol resin, a polystyrene resin, and a combination thereof.

The insulating material 140 may be formed to fill the voids of the porous scaffold 130. Further, as illustrated in FIG. 1, the insulating material 140 may also be formed in upper and lower portions of the porous scaffold 130. However, a form in which the insulating material 140 is formed is not limited thereto. That is, when the insulating material 140 fills the voids of the porous scaffold 130, whether the insulating material 140 is formed in the upper and lower portions of the porous scaffold 130, a thickness of the insulating material, and the like may be changed depending on the selection of those skilled in the art. According to the preferred embodiment of the present invention, the insulating material may be a resin in which a reinforcing material, such as a glass fiber and an inorganic filter, is impregnated in an epoxy resin. For example, the insulating material may be a prepreg.

The metal layer 150 may be formed in the insulating material 140. According to the preferred embodiment of the present invention, the metal layer 150 may be formed on a surface opposite to a surface which fills the voids of the porous scaffold 130. The metal layer 150 is patterned to be able to serve as a circuit pattern.

The vias 170 may be formed at both sides of the electronic device 110 which is embedded into the core substrate 100. According to the preferred embodiment of the present invention, the via 170 may be a through via which penetrates through the core substrate 100. Therefore, an upper portion of the via 170 may adhere to the metal layer 150 and the side surface thereof may adhere to the internal electrode 111 of the electronic device 110. The electronic device 110 may be electrically connected to the metal layer 150 by the so formed via 170. According to the preferred embodiment of the present invention, the via 170 is illustrated as the through via, but is not limited thereto. That is, the form of the via 170 may be formed in any form which may electrically connect the metal layer 150 to the internal electrode 111 of the electronic device 110.

The so formed core substrate 100 is formed not to have a void from the embedded electronic device 110, thereby making an adhesion therebetween excellent.

FIGS. 2 to 8 are exemplified diagrams illustrating a method for manufacturing a core substrate according to a preferred embodiment of the present invention.

Referring to FIG. 2, the electronic device 110 may be mounted on a firing substrate 300.

The firing substrate 300 is mounted with the electronic device 110 and may serve to support the electronic device 110 and polymer slurry (not illustrated) during a firing process. The firing substrate 300 may be made of ceramics. However, a material of the firing substrate 300 is not limited to the ceramics, but any material having physical and chemical stability may be used in the range of a firing temperature.

The electronic device 110 mounted on the firing substrate 300 may be, for example, a multi layer ceramic capacitor (MLCC) in which the external electrode is not formed. That is, the internal electrodes 111 may be formed so as to be exposed from both surfaces of the electronic device 110. The electronic device 110 having the internal electrodes 111 exposed from both surfaces thereof may be horizontally mounted on the firing substrate 300. The internal electrode 111 according to the preferred embodiment of the present invention has stability at a firing temperature, and any material which may be used for the internal to electrode of the MLCC may be applied.

Further, the electronic device 110 according to the preferred embodiment of the present invention may be an MLCC which does not suffer from the sintering and firing process. That is, the electronic device 110 may be a device which has a green sheet and the internal electrode stacked and pressed and is cut at a desired size.

The preferred embodiment of the present invention describes that the electronic device 110 is the MLCC which does not suffer from the sintering and firing processes, but is not limited thereto, but may be applied to the MLCC which suffers from the firing process.

Referring to FIG. 3, the polymer slurry 120 may be applied and sintered on the firing substrate 300.

First, the polymer slurry 120 may be applied on the firing substrate 300. The polymer slurry 120 may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of porous inorganic material and urea resin, phenol resin, a polystyrene resin, and a combination thereof.

Next, the polymer slurry 120 applied on the firing substrate 300 may be sintered.

In this case, the electronic device 110 may be sintered as soon as the polymer slurry 120 is sintered.

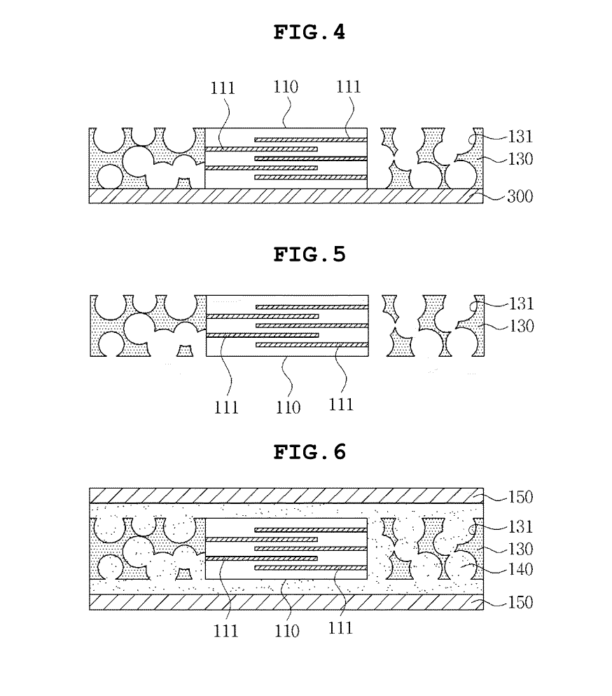

Referring to FIG. 4, the porous scaffold 130 may be formed.

The polymer slurry 120 which is sintered on the firing substrate 300 may suffer from the firing processing. For example, the polymer slurry 120 may suffer from the firing processing at about 200° C. The firing processing temperature may be changed depending on a material forming the polymer slurry 120.

When the polymer slurry 120 suffers from the firing processing, the polymer is decomposed and a portion in which the polymer is present may be a void 131. That is, the polymer is removed by performing the firing processing on the polymer slurry 120, thereby forming the porous scaffold 130 having the void 131.

In this case, the electronic device 110 may simultaneously suffer from the firing processing.

As described above, the polymer slurry 120 and the electronic device 110 may simultaneously suffer from the firing processing. Therefore, the firing processing process of the electronic device 110 may be removed, such that manufacturing costs and time may be more reduced than in the case of performing the separate firing processing on the electronic device 110.

Referring to FIG. 5, the firing substrate 300 may be removed.

When the firing substrate 300 is removed, the porous scaffold 130 embedded with the electronic device 110 remains.

Referring to FIG. 6, the core substrate 100 may be formed.

The insulating material 140 may be stacked and pressed on the porous scaffold 130 embedded with the electronic device 110. According to the preferred embodiment of the present invention, the insulating material 140 may be a prepreg. Further, according to the preferred embodiment of the present invention, one surface of the insulating material 140 may be provided with the metal layer 150. The metal layer 150 may be formed on a surface opposite to a surface which contacts the porous scaffold 130.

When the insulating material 140 is stacked and pressed on the porous scaffold 130, the insulating material 140 may be filled in the void 131 of the porous scaffold 130. Further, the insulating material 140 may also be formed in the upper and lower portions of the porous scaffold 130. The core substrate 100 embedded with the electronic device 110 may be formed by the above process.

According to the preferred embodiment of the present invention, an example in which the one surface of the insulating material 140 is provided with the metal layer 150 is described, but the preferred embodiment of the present invention is not limited thereto. The to insulating material 140 and the metal layer 150 may be sequentially formed as separate components by the selection of those skilled in the art.

According to the prior art, when the electronic device is mounted by forming the cavity on the core substrate, the problems of crack, breakage, deformation, and the like may occur due to the occurrence of voids between the core substrate and the electronic device. However, the core substrate 100 according to the preferred embodiment of the present invention is formed by stacking and pressing the insulating material 140 on the porous scaffold 130 into which the electronic device 110 is embedded, such that there is no void between the electronic device 110 and the core substrate 100, thereby making the adhesion therebetween excellent. Therefore, as in the prior art, the problems caused by the voids between the core substrate 100 and the electronic device 110 may be prevented.

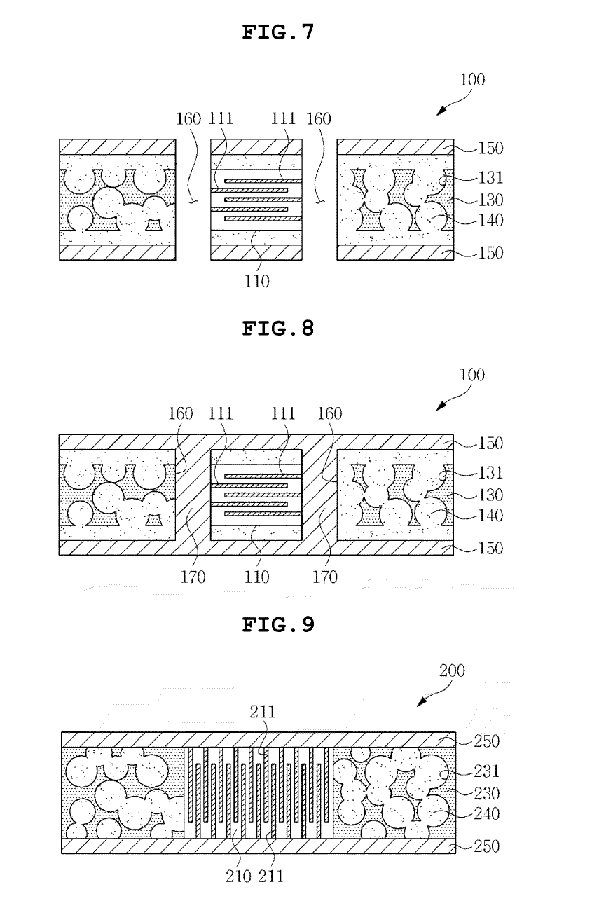

Referring to FIG. 7, a via hole 160 may be formed on the core substrate 100.

The via hole 160 according to the preferred embodiment of the present invention is a through via hole and therefore may be formed so that the core substrate 100 penetrates through the via hole 160. In this case, the via hole 160 may be formed to expose the internal electrode 111 of the electronic device 110 which is embedded into the core substrate 100. The via hole 160 may be formed by a laser drill. In addition, the via hole 160 may be formed by a method for forming a via hole which is known in a circuit board field.

Referring to FIG. 8, a via 170 may be formed on the core substrate 100.

The via 170 may be formed by forming a conductive material in the via hole 160 of the core substrate 100. For example, the via 170 may be made of copper. A material forming the via 170 is not limited to the copper, but any conductive material used in the substrate field may be used. Further, the via 170 may be formed by the method for forming a via which is known in the circuit board field.

The upper portion of the via 170 may adhere to the metal layer 150 and the side thereof may adhere to the internal electrode 111 of the electronic device 110. Therefore, the metal layer 150 and the electronic device 110 of the core substrate 100 may be electrically connected to each other by the via 170.

Although the preferred embodiment of the present invention describes that the via 170 is formed to have a through via form, the form of the via 170 is not limited thereto. The via 170 may be formed to have any form in which may electrically connect the metal layer 150 to the internal electrode 111 of the electronic device 110.

Further, although not illustrated in the preferred embodiment of the present invention, the metal layer 150 may be patterned by the selection of those skilled in the art.

FIG. 9 is an exemplified diagram illustrating a core substrate according to another preferred embodiment of the present invention.

Referring to FIG. 9, a core substrate 200 according to a preferred embodiment of the present invention may be embedded with an electronic device 210.

The electronic device 210 may be embedded into the core substrate 200. The electronic device 210 according to the preferred embodiment of the present invention may be the multi layer ceramic capacitor (MLCC) in which an external electrode is not formed.

Internal electrodes 211 may be exposed on both surfaces of the electronic device 210. The internal electrode 211 according to the preferred embodiment of the present invention has stability at a firing temperature, and any material which may be used for the internal electrode of the MLCC may be applied. Further, according to the preferred embodiment of the present invention, the internal electrodes 211 may be formed on upper and lower surfaces of the electronic device 210. Here, forming the internal electrodes 211 on the upper and lower surfaces of the electronic device 210 is to describe the fact that the internal electrodes 211 are exposed on a parallel line of a metal layer 250. As illustrated in FIG. 9, the electronic device 210 having the internal electrodes 211 exposed on both sides thereof may be a device which is vertically embedded into the core substrate 200.

The core substrate 200 may include a porous scaffold 230, an insulating material 240, and a metal layer 250.

The porous scaffold 230 may have a porous structure including a plurality of voids. The porous scaffold 230 according to the preferred embodiment of the present invention may be made of a material having excellent thermal stability. For example, the porous scaffold 230 may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of porous inorganic material and urea resin, phenol resin, a polystyrene resin, and a combination thereof.

The insulating material 240 may be formed to fill the voids of the porous scaffold 230. Further, as illustrated in FIG. 9, the insulating material 240 may also be formed in upper and lower portions of the porous scaffold 230. However, a form in which the insulating material 240 is formed is not limited thereto. That is, when the insulating material 240 fills the voids of the porous scaffold 230, whether the insulating material 240 is formed in the upper and lower portions of the porous scaffold 230, a thickness of the insulating material, and the like may be changed depending on the selection of those skilled in the art. According to the preferred embodiment of the present invention, the insulating material may be a resin in which a reinforcing material, such as a glass fiber and an inorganic filter, is impregnated in an epoxy resin. For example, the insulating material may be a prepreg.

The metal layer 250 may be formed in the insulating material 240. According to the preferred embodiment of the present invention, the metal layer 250 may be formed on a surface opposite to a surface which fills the voids of the porous scaffold 230. The metal layer 250 is patterned to be able to serve as a circuit pattern. Further, the metal layer 250 may contact the internal electrode 211 of the electronic device 210. The metal layer 250 contacts the internal electrode 211 of the electronic device 210, such that the metal layer 250 and the internal electrode 211 may be electrically connected to each other without a separate component.

The so formed core substrate 200 is formed not to have a void from the embedded electronic device 210, thereby making an adhesion therebetween excellent.

FIGS. 10 to 14 are exemplified diagrams illustrating a method for manufacturing a core substrate according to another preferred embodiment of the present invention.

Referring to FIG. 10, the electronic device 210 may be mounted on the firing substrate 300.

The firing substrate 300 is mounted with the electronic device 210 and may serve to support the electronic device 210 and polymer slurry (not illustrated) during a firing process. The firing substrate 300 may be made of ceramics. However, a material of the firing substrate 300 is not limited to the ceramics, but any material having physical and chemical stability may be used in the range of a firing temperature.

The electronic device 210 mounted on the firing substrate 300 may be, for example, a multi layer ceramic capacitor (MLCC) in which the external electrode is not formed. That is, the internal electrodes 211 may be formed so as to be exposed from both surfaces of the electronic device 210. That is, the electronic device 210 having the internal electrodes 211 exposed on the upper and lower surfaces thereof may be horizontally mounted on the firing substrate 300. Alternatively, the electronic device 210 having the internal electrodes 211 exposed on both sides thereof may be vertically mounted on the firing substrate 300. Therefore, only the internal electrode 211 exposed on the lower surface of the electronic device 210 may contact the firing substrate 300. The internal electrode 211 according to the preferred embodiment of the present invention has stability at a firing temperature, and any material which may be used for the internal electrode of the MLCC may be applied.

Further, the electronic device 210 according to the preferred embodiment of the present invention may be an MLCC which does not suffer from the sintering and firing process. That is, the electronic device 210 may be a device which has a green sheet and the internal electrode stacked and pressed and is cut at a desired size.

The preferred embodiment of the present invention describes that the electronic to device 210 is the MLCC which does not suffer from the sintering and firing processes, but is not limited thereto, but may be applied to the MLCC which suffers from the firing process.

Referring to FIG. 11, the polymer slurry 220 may be applied and sintered on the firing substrate 300.

First, the polymer slurry 220 may be applied on the firing substrate 300. The polymer slurry 220 may be made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of porous inorganic material and urea resin, phenol resin, a polystyrene resin, and a combination thereof.

In this case, the polymer slurry 220 may be applied to have a height lower than the electronic device 210. That is, the polymer slurry 220 may be applied so that the internal electrode 211 of the upper surface of the electronic device 210 is exposed.

Next, the polymer slurry 220 applied on the firing substrate 300 may be sintered.

In this case, the electronic device 210 may be sintered as soon as the polymer slurry 220 is sintered.

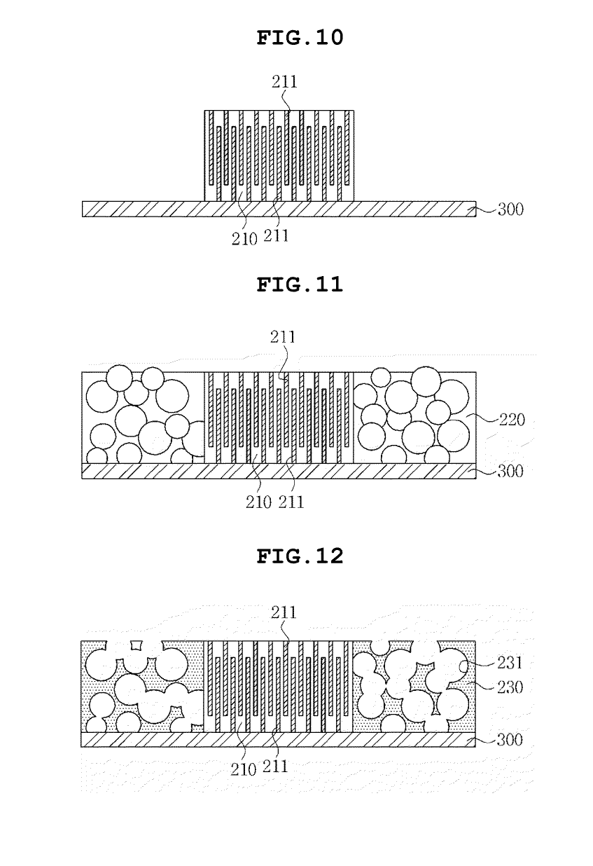

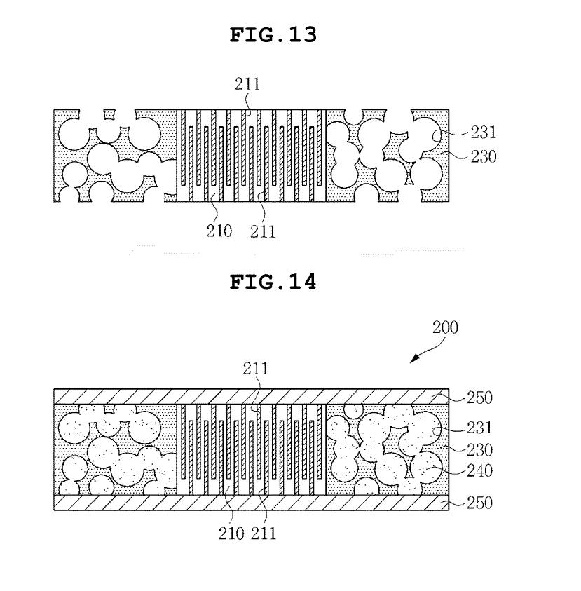

Referring to FIG. 12, the porous scaffold 230 may be formed.

The polymer slurry 220 which is sintered on the firing substrate 300 may suffer from the firing processing. For example, the polymer slurry 220 may suffer from the firing processing at about 200° C. The firing processing temperature may be changed depending on a material forming the polymer slurry 220.

When the polymer slurry 220 suffers from the firing processing, the polymer is decomposed and a portion in which the polymer is present may be a void 231.

That is, the polymer is removed by performing the firing processing on the polymer slurry 220, thereby forming the porous scaffold 230 having the void 231.

In this case, the electronic device 210 may simultaneously suffer from the firing processing.

As described above, the polymer slurry 220 and the electronic device 210 may simultaneously suffer from the firing processing. Therefore, it is possible to more reduce the manufacturing costs and time than in the case in which the firing processing of the electronic device 210 is separately performed. Therefore, the firing processing process of the electronic device 210 may be removed, such that manufacturing costs and time may be more reduced than in the case of performing the separate firing processing on the electronic device 210.

Referring to FIG. 13, the firing substrate 300 may be removed.

When the firing substrate 300 is removed, the porous scaffold 230 embedded with the electronic device 210 remains.

Referring to FIG. 14, the core substrate 200 may be formed.

The insulating material 240 may be stacked and pressed on the porous scaffold 230 embedded with the electronic device 210. According to the preferred embodiment of the present invention, the insulating material 240 may be a prepreg. Further, according to the preferred embodiment of the present invention, one surface of the insulating material 240 may be provided with the metal layer 250. The metal layer 250 may be formed on a surface opposite to a surface which contacts the porous scaffold 230.

When the insulating material 240 is stacked and pressed on the porous scaffold 230, the insulating material 240 may be filled in the void 231 of the porous scaffold 230. Further, the insulating material 240 may also be formed in the upper and lower portions of the porous scaffold 230. The core substrate 200 embedded with the electronic device 210 may be formed by the above process. Further, the metal layer 250 may contact the internal electrode 211 of the electronic device 210. The metal layer 250 contacts the internal electrode 211 of the electronic device 210, such that the metal layer 250 and the electronic device 210 may be electrically connected to each other without a separate component.

According to the preferred embodiment of the present invention, an example in which the one surface of the insulating material 240 is provided with the metal layer 250 is described, but the preferred embodiment of the present invention is not limited thereto. The insulating material 240 and the metal layer 250 may be sequentially formed as separate components by the selection of those skilled in the art.

Further, although not illustrated in the preferred embodiment of the present invention, the metal layer 250 may also be patterned by the selection of those skilled in the art.

According to the prior art, when the electronic device is mounted by forming the cavity on the core substrate, the problem of crack, breakage, deformation, and the like may occur due to the occurrence of voids between the core substrate and the electronic device. However, the core substrate 200 according to the preferred embodiment of the present invention is formed by stacking and pressing the insulating material 240 on the porous scaffold 230 into which the electronic device 210 is embedded, such that there is no void between the electronic device 210 and the core substrate 200, thereby making the adhesion therebetween excellent. Therefore, as in the prior art, the problems caused by the voids between the core substrate 200 and the electronic device 210 may be prevented.

Further, the process of forming an external electrode of the electronic device 210 may be removed by directly adhering the metal layer 250 to the internal electrode 211 of the electronic device 210. Therefore, it is possible to reduce the time and costs to form the external electrode of the electronic device 210.

According to the core substrate and the method for manufacturing the same according to the preferred embodiments of the present invention, it is possible to improve the adhesion between the core substrate and the electronic devices.

Further, according to the core substrate and the method for manufacturing the same according to the preferred embodiments of the present invention, it is possible to reduce the occurrence of deformation, cracks, damages, and the like, by improving the adhesion with the electronic devices.

In addition, according to the core substrate and the method for manufacturing the same according to the preferred embodiments of the present invention, it is possible to reduce costs and time by removing the process of firing electronic devices and the process of forming an external electrode.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A core substrate, comprising:
a porous scaffold formed with a void;
an insulating material formed to fill a void of the porous scaffold; and
an electronic device embedded into the porous scaffold and the insulating material and having internal electrodes exposed on both surfaces thereof.

2. The core substrate as set forth in claim 1, wherein the porous scaffold is made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of urea resin, phenol resin, a polystyrene resin, and a combination thereof.

3. The core substrate as set forth in claim 1, wherein the insulating material is a prepreg.

4. The core substrate as set forth in claim 1, wherein the internal electrodes are exposed from both surfaces of the electronic device.

5. The core substrate as set forth in claim 1, wherein the internal electrodes are exposed from upper and lower surfaces of the electronic device.

6. The core substrate as set forth in claim 1, further comprising:
a metal layer formed on a surface opposite to a surface which contacts the porous scaffold of the insulating material.

7. The core substrate as set forth in claim 6, further comprising:
vias formed on both sides of the electronic device to electrically connect the metal layer to the internal electrode.

8. The core substrate as set forth in claim 6, wherein the metal layer is electrically connected to the internal electrode by contacting the internal electrode.

9. The core substrate as set forth in claim 1, wherein the electronic device is a multi layer ceramic capacitor (MLCC).

10. A method for manufacturing a core substrate, comprising:
mounting electronic devices having internal electrodes exposed on both surfaces thereof on a firing substrate;
applying and sintering a polymer slurry on the firing substrate;
forming a porous scaffold by firing the sintered polymer slurry;
removing the firing substrate; and
filling the insulating material in a void of the porous scaffold by stacking and pressing an insulating material on one surface or both surfaces of the porous scaffold.

11. The method as set forth in claim 10, wherein the polymer slurry is made of at least one selected from at least one porous inorganic material which is selected from the group consisting of aerogel, silica, fused silica, glass, alumina, platinum, nickel, titania, zirconia, ruthenium, cobalt and combinations thereof and at least one porous polymer which is selected from the group consisting of urea resin, phenol resin, a polystyrene resin, and a combination thereof.

12. The method as set forth in claim 10, wherein in the filling of the insulating material in the void of the porous scaffold, the insulating material is a prepreg.

13. The method as set forth in claim 10, further comprising:
after the filling of the insulating material in the void of the porous scaffold, forming a metal layer formed on a surface opposite to a surface which contacts the porous scaffold of the insulating material.

14. The method as set forth in claim 13, further comprising:
after the forming of the metal layer,
forming a via hole on the porous scaffold and the insulating material so that the internal electrode of the electronic device is exposed; and
electrically connecting the metal layer with the internal electrode by forming a conductive material in the via hole.

15. The method as set forth in claim 13, wherein in the forming of the metal layer, the metal layer is electrically connected to the internal electrode of the electronic device by contacting the internal electrode of the electronic device.

16. The method as set forth in claim 10, wherein in the filling of the insulating material in the void of the porous scaffold, the insulating material further includes a metal layer formed on a surface opposite to a surface which contacts the porous scaffold.

17. The method as set forth in claim 16, further comprising:
after the filling of the insulating material in the void of the porous scaffold,
forming a via hole on the porous scaffold and the insulating material so that the internal electrode of the electronic device is exposed; and
electrically connecting the metal layer with the internal electrode by forming a conductive material in the via hole.

18. The method as set forth in claim 16, wherein in the filling of the insulating material in the void of the porous scaffold, the metal layer is electrically connected to the internal electrode of the electronic device by contacting the internal electrode of the electronic device.

19. The method as set forth in claim 10, wherein the internal electrodes are exposed from both surfaces of the electronic device.

20. The method as set forth in claim 10, wherein the internal electrodes are exposed from upper and lower surfaces of the electronic device.

21. The method as set forth in claim 10, wherein the electronic device is a multi layer ceramic capacitor (MLCC).

22. The method as set forth in claim 10, wherein the electronic device is in a non-sintered and non-firing state.

23. The method as set forth in claim 22, wherein in the applying and sintering of the polymer slurry on the firing substrate, the electronic device is sintered.

24. The method as set forth in claim 22, wherein in the forming of the porous scaffold by firing the sintered polymer slurry, the electronic device is fired.
